(19) United States
(12) Patent Application Publication
(10) Pub. No.: US 2025/0087401 A1
(43) Pub. Date: Mar. 13, 2025

(54) VARIABLE INDUCTOR AND INDUCTOR MODULE

(71) Applicant: DB HiTek Co., Ltd., Bucheon-si (KR)

(72) Inventor: Jung Ah KIM, Dongducheon-si (KR)

(21) Appl. No.: 18/498,185

(22) Filed: Oct. 31, 2023

(30) Foreign Application Priority Data
Sep. 11, 2023 (KR) 10-2023-0120447

(51) Int. Cl. H01F 21/12; B81B 3/00

(52) U.S. Cl. CPC H01F 21/12; B81B 3/0056; B81B 2203/0181

(57) ABSTRACT

Disclosed is a variable inductor or inductor module with a varying inductance, wherein the variable inductor or inductor module changes inductor ring spacing and the distance between the inductor and a substrate using a MEMS driver, thereby enabling variances in the inductance.

### CROSS REFERENCE TO RELATED APPLICATION

The present application claims priority to Korean Patent Application No. 10-2023-0120447, filed Sep. 11, 2023, the entire contents of which are incorporated herein for all purposes by this reference.

### BACKGROUND OF THE INVENTION

### Field of the Invention

The present disclosure relates to a variable inductor or inductor module capable of varying an inductance value even after the variable inductor or inductor module is manufactured.

### Description of the Related Art

Generally, conventional inductors are classified into a solenoid inductor with a conducting wire wound several times at a particular radius, and a spiral inductor with conducting wire wound (arranged) several times with a particular spacing in a single plane. Such inductors are used in a radio frequency integrated circuit (RF IC) or a monolithic micro IC.

Typically, inductors are fabricated by winding metal above a substrate. A general inductor has an inductance value caused by the wound metal. Herein, the inductance value of the general inductor is determined by adding parasitic components, such as resistance of the metal, capacitance between the metal and the substrate, and capacitance between adjacent metal structures.

A general inductor is manufactured with the above parameters predetermined, and generally has a fixed inductance value. Therefore, the general inductor is a fixed inductor, and its use is limited due to its fixed reactance.

One way to enhance the usefulness of conventional inductors is to make the inductance value variable, even after the inductor is manufactured. For example, in the industry, a variable inductor capable of varying (adjusting) an inductance value is under development for use in a tunable VCO or a tunable LNA used in multi-frequency band ICs.

The foregoing is intended merely to aid in the understanding of the background of the present disclosure, and is not intended to mean that the present disclosure falls within the purview of the related art that is already known to those skilled in the art.

### DOCUMENT OF RELATED ART

Korean Patent Application Publication No. 10-2023-0078183.

### SUMMARY OF THE INVENTION

The present disclosure is directed to providing a variable inductor or inductor module that changes inductor spacing and spacing between inductor metal and a substrate (e.g., supporting the inductor) using one or more micro-electromechanical system (MEMS) structures, thereby enabling variance in the inductance value. That is, the present disclosure is directed to providing a variable inductor or inductor module that allows the shape of the inductor to be changed depending on the displacement of a MEMS driver driven by an electrostatic force, thereby enabling the inductor to have a variable inductance.

According to first embodiment of the present disclosure, there is provided a variable inductor or inductor module including a substrate; an inductor coil (e.g., in a loop) above the substrate, and having a reference inductance value (e.g., in a default position); and a micro-electromechanical system (MEMS) driver that responds to an electrostatic force configured to be turned on or off in response to a control signal, and is configured to raise increase a distance between at least part of the inductor coil and the substrate (e.g., in response to the electrostatic force) when the MEMS driver is turned on, and to maintain the inductor coil in the default position (e.g., in the absence of the electrostatic force) when the MEMS driver is turned off.

The inductor coil may, when the driver is turned on, have an inductance value different from the reference inductance value (e.g., when the distance between at least part of the inductor coil and the substrate is increased).

The inductor coil may comprise a loop, the driver may be connected to a central portion (e.g., a center) of the loop, and the inductor coil may have a spiral shape when the driver is turned on so that spacing between both (1) adjacent rings of the inductor coil and (2) the substrate and the inductor coil change. Herein, a “ring” of the inductor coil may refer to a continuous section of the inductor coil that has angles and/or arcs totaling 360°, but which does not form a closed shape.

The inductor coil may be configured such that, when the driver is turned on, the distance between the substrate and a ring of the inductor coil increases as a distance of the ring from the peripheral edge or circumference of the inductor coil increases.

The driver may include a vertical bar or other structure connected to the substrate; a driving bar connected to the inductor coil, and configured to raise or lower the inductor coil by rotating around a pivot (e.g., at a second end or along a length of the vertical bar); a first electrode on the driving bar; and a second electrode on the substrate and at least partially overlapping the first electrode. The driving bar may include a vertical portion having a first end connected to the inductor coil; and a horizontal portion having a first end connected to a second end of the vertical portion, wherein the horizontal portion is rotatable around the pivot.

The driver may be configured to control the distance between the inductor coil and the substrate depending on the electrostatic force (e.g., a magnitude of the force between the electrodes), and the inductor coil may have a different inductance value depending on the electrostatic force (e.g., the inductance value may correspond or be proportional to the electrostatic force).

According to a second embodiment of the present disclosure, there is provided a variable inductor or inductor module including a substrate; an inductor coil comprising a plurality of split coils connected to each other above the substrate, the inductor coil having a reference inductance value (e.g., in a default position); and a plurality of micro-electromechanical system (MEMS) drivers that respond to a plurality of electrostatic forces, wherein the plurality of MEMS drivers are respectively connected to the plurality of split coils, configured to be turned on or off in response to a plurality of control signals, and configured to increase a distance between the split coils and the substrate when turned on, and to maintain the split coils in a default position when turned off.

The inductor coil comprising the plurality of split coils may having an inductance value different from the reference inductance value when at least one of the plurality of drivers is turned on and/or at least one distance between at least one of the plurality of split coils and the substrate increases.

The plurality of split coils may have any of a plurality of different distances from the substrate depending on the electrostatic forces (e.g., the magnitude[s] of the force[s] between corresponding electrodes). The distance of each of the split coils from the substrate may be independent from the distance(s) of other(s) of the split coils from the substrate. For example, the inductor coil may have a wave-like shape when alternating ones of the plurality of drivers are on and remaining ones of the plurality of drivers are off.

Each of the plurality of drivers may be connected to the inductor coil at a position at which one of the split coils and another one of the split coils are connected to each other. Alternatively, each of the plurality of drivers may be connected to a corresponding unique one of the split coils, at a position in a center of the corresponding unique one of the split coils. In such an alternative embodiment, each of the split coils is, or is approximately, a half-ring.

According to a third embodiment of the present disclosure, there is provided a variable inductor or inductor module including a substrate; a multi-coil inductor including a first coil and a second coil, each of which is above the substrate, and having respective first and second inductance values; a first micro-electromechanical system (MEMS) driver that responds to a first electrostatic force, configured to be turned on or off in response to a first control signal, and configured to increase a first distance between the first coil and the substrate when turned on, and to maintain the first coil in a first default position when turned off, and a second MEMS driver that responds to a second electrostatic force, configured to be turned on or off in response to a second control signal, and configured to increase a second distance between the second coil and the substrate when turned on, and to maintain the second coil in a second default position when turned off.

The Inductor coil may have any of a plurality of different inductance values depending on driving states of the first driver and the second driver.

The first driver may be connected to a central portion (e.g., a center) of the first coil, and when the first driver is turned, spacing between adjacent rings of the first coil and the distance between the substrate and the first coil change. Herein, the first coil may have a spiral shape, and when the first driver is turned on, the distance between the substrate and a ring of the first coil increases as a distance of the ring from the peripheral edge or circumference of the first coil increases.

The second driver may be connected to a central portion (e.g., a center) of the second coil, and when the second driver is turned, spacing between (1) adjacent rings of the second coil and (2) the substrate and the second coil change. Herein, the second coil may have a spiral shape, and when the second driver is turned on, the distance between the substrate and a ring of the second coil increases as a distance of the ring from a peripheral edge or circumference of the second coil increases.

When the first driver and the second driver may respectively receive independent first and second control signals, and when the first and second control signals have different values, the first coil raised by the first driver may be different from a raised height of the second coil raised by the second driver.

The first driver may include a first vertical structure connected to the substrate; a first driving bar connected to the first coil, and configured to raise or lower the first coil by rotating around a first pivot; a first electrode on the first driving bar; and a second electrode on the substrate and at least partially overlapping the first electrode, wherein the first driving bar may include a first vertical portion having a first end connected to the first coil; and a first horizontal portion having a first end connected to a second end of the first vertical portion, and connected to the first vertical structure such that the first horizontal portion is rotatable around the first pivot.

The second driver may Ide a second vertical structure connected to the substrate; a second driving bar connected to the second coil, and configured to raise or lower the second coil by rotating around a second end of the second vertical bar; a third electrode on the second driving bar; and a fourth electrode on the substrate and at least partially overlapping the third electrode, wherein the second driving bar may include a second vertical portion having a first end connected to the second coil; and a second horizontal portion having a first end connected to a second end of the second vertical portion, and connected to the second vertical structure such that the second horizontal portion is rotatable around the second pivot.

According to the present disclosure, a variable inductor or inductor module changes an inductor coil having a loop into a spiral shape using a driver, thereby adjusting inductor ring spacing and spacing between the inductor coil and the substrate.

In addition, a variable inductor or inductor module changes an inductor coil having a loop into a spiral shape using a driver, thereby varying the inductance of a single inductor coil.

It is noted that, although not explicitly described herein, any advantageous effects tentative or otherwise, that are expected from technical features of the present disclosure are regarded as being explicitly or implicitly described in the present specification.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a perspective view illustrating a variable inductor or inductor module according to a first embodiment of the present disclosure;

FIG. 2 is a cross-sectional view illustrating a driver of the variable inductor or inductor module of FIG. 1;

FIG. 3 is a diagram illustrating a raising or inductance-changing operation of an inductor coil caused by the operation of the driver of FIG. 1;

FIG. 4 is a diagram illustrating the variable inductor or inductor module and inductance characteristic when the driver of FIG. 1 is off and in a default position;

FIG. 5 is a diagram illustrating the variable inductor or inductor module and inductance characteristic when the driver of FIG. 1 is on;

FIG. 6 is a perspective view illustrating a variable inductor or inductor module according to a second embodiment of the present disclosure;

FIGS. 7 and 8 are diagrams illustrating the operation of the variable inductor or inductor module of FIG. 6;

FIG. 9 is a perspective view illustrating a variable inductor or inductor module according to a third embodiment of the present disclosure; and

FIGS. 10 to 13 are diagrams illustrating the operation of the variable inductor or inductor module of FIG. 9.

### DETAILED DESCRIPTION OF THE INVENTION

Hereinafter, embodiments of the present disclosure will be described in detail with reference to the accompanying drawings. It is noted that the embodiments of the present disclosure may be changed to a variety of other embodiments. The scope of the present disclosure should not be interpreted as being limited to the embodiments described hereinbelow, but should be interpreted on the basis of the descriptions in the appended claims. In addition, the embodiments of the present disclosure are provided for reference in order to fully describe the disclosure for those skilled in the art.

Unless otherwise mentioned in context, a singular noun or a singular noun phrase may have a plural meaning through the present specification. The terms “comprise” and/or “comprising” are intended to indicate that a shape, a number, a step, an operation, a member, an element, and/or a group thereof, etc., are present, and should be understood not to preclude the presence or addition of one or more other shapes, numbers, steps, operations, members, elements, and/or groups thereof.

It should be noted that, in a case where one element (or layer) is described as being on another element (or layer), this means that the one element may be directly on the other element, or that one or more third elements or layers may be therebetween. In addition, in the case where one element is described as being directly on the top of one other element, no third element is therebetween. In addition, positioning on a “top”, “upper portion”, or “lower portion” of one element, positioning “above” or “below” one element, or positioning on “one lateral side”, or a “lateral surface” of one element means a relative positional relationship.

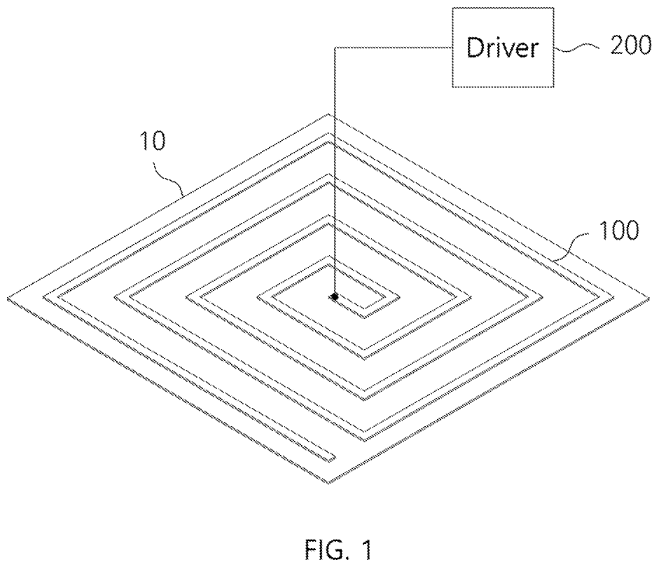

Referring to FIG. 1, a variable inductor or inductor module according to a first embodiment of the present disclosure includes an inductor coil 100 and a driver 200.

The inductor coil 100 is over a substrate 10. The inductor coil 100 is a loop-shaped coil that contains a plurality of rings and is wound multiple times over the substrate 10. The inductor coil 100 comprises a conductive material, such as copper, silver, gold, aluminum or iron, for example, and has an inductance.

As the inductor coil 100 is in a loop, the inductor coil 100 has an inductance value that is proportional to the coil length, coil spacing, the number of turns or rings in the coil, and the line width of the coil. Herein, an inductance of the inductor coil 100 when the inductor coil 100 is in a default position over the substrate 10 (e.g., when the driver 200 is off) is defined as a reference inductance value.

The driver 200 is connected to the inductor coil 100, and more specifically, the driver 200 is connected to the inductor coil 100 at a central portion (e.g., the center) of the coil (e.g., an internal end of the inductor coil 100). The driver 200 is driven according to a control signal and changes the spacing or distance between the inductor coil 100 and the substrate 10, as well as the spacing between rings or turns of the inductor coil 100. Herein, the driver 200 raises or lowers the inductor coil 100, and when the driver 200 raises the inductor coil 100, the inductor coil 100 has an inductance value different from the reference inductance value. When the driver 200 lowers the inductor coil 100, it returns the inductor coil 100 to the default position.

The driver 200 raises the central portion of the inductor coil 100 when turned on, and lowers the raised portion(s) of the inductor coil 100 when turned off. Herein, the driver 200 comprises a micro-electromechanical system (MEMS) driver, for example.

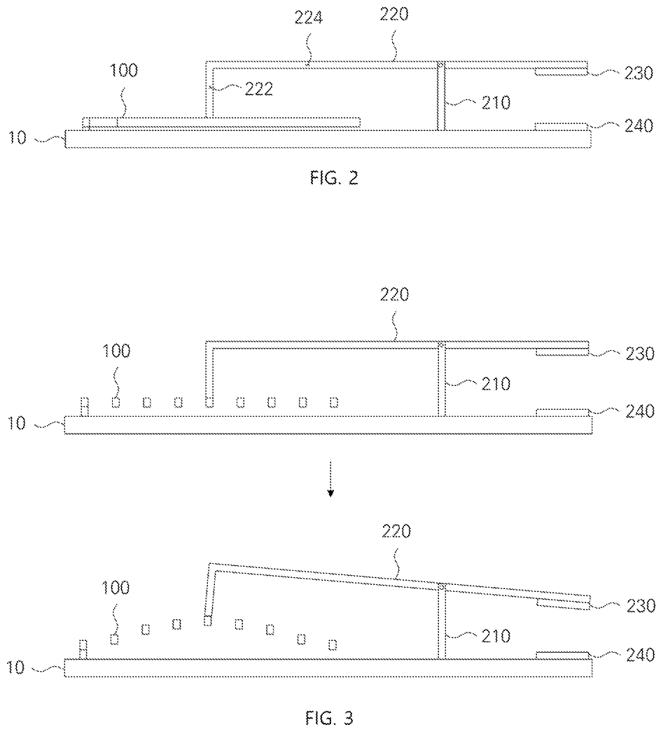

For example, referring to FIG. 2, the driver 200 includes a vertical structure (e.g., a bar) 210, a driving bar 220, a first electrode 230, and a second electrode 240.

The vertical structure 210 elevates the driving bar 220 from the substrate to a position or height above the inductor coil 100 and functions as a pivot for the driving bar 220. A first end of the vertical structure 210 is connected to the substrate 10, and a second end of the vertical structure 210 is connected to the driving bar 220. Herein, the second end of the vertical structure 210 is connected to the driving bar 220 such that the driving bar 220 is rotatable around the second end of the vertical structure 210 (i.e., the pivot).

The driving bar 220 raises the inductor coil 100 or maintains the inductor coil 100 in the default position. The driving bar 220 includes a vertical portion 222 and a horizontal portion 224.

A first end of the vertical portion 222 is connected to the inductor coil 100. A second end of the vertical portion 222 is connected to the horizontal portion 224.

A first end of the horizontal portion 224 is connected to the second end of the vertical portion 222. Thus, the driving bar 220 has a bent shape (e.g., an “L” shape), for example.

The horizontal portion 224 is connected to the second end of the vertical structure 210 such that the horizontal portion 224 is rotatable around the second end of the vertical structure 210. Herein, the vertical structure 210 is between the first end of the horizontal portion 224 and a second end of the horizontal portion 224, and has a height from the substrate 10 significantly greater than the height of the inductor coil 100 from the substrate 10. Herein, the second end of the horizontal portion 224 is an end opposite to the first end of the horizontal portion 224.

The first electrode 230 receives a first voltage (e.g., from a driving circuit [not shown] elsewhere on the substrate, or external to the substrate) that may form an electrostatic force (e.g., between it and a voltage on the second electrode 240, described elsewhere). The first electrode 230 may be on the driving bar 220 (e.g., on a surface facing the substrate 10). Specifically, the first electrode 230 is at or close to the second end of the horizontal portion 224. Accordingly, the first electrode 230 may be at one end of the horizontal portion 224 of the driving bar 220, with the connection position between the vertical structure 210 and the driving bar 220 in the middle of the horizontal portion 224.

The second electrode 240 receives a second voltage (e.g., from the same or different driving circuit on or external to the substrate that provides the first voltage) that may form the electrostatic force between it and the first electrode 230. For example, when one of the first and second voltages is positive and the other is negative, a non-zero electrostatic force is generated between the first and second electrodes 230 and 240 (i.e., the driver 200 is “on”), and the first and second electrodes 230 and 240 move towards each other. However, when the first and second voltages are identical or substantially identical, no electrostatic force is generated between the first and second electrodes 230 and 240 (i.e., the driver 200 is “off”), and the inductor coil 100 returns to or is maintained in the default position above the substrate 10. The second electrode 240 is on the substrate 10. More specifically, the second electrode 240 at least partially overlaps the first electrode 230.

Herein, the first electrode 230 and the second electrode 240 attract each other as the electrostatic force increases, thereby raising the vertical portion 222 of the driving bar 220. The attractive force between the first electrode 230 and the second electrode 240 decreases as the electrostatic force decreases, thereby lowering the vertical portion 222 of the driving bar 220 towards the default position.

Referring to FIG. 3, when an appropriate external control signal is input, an electrostatic force forms between the first electrode 230 and the second electrode 240, bringing the first electrode 230 and the second electrode 240 towards each other.

As the first electrode 230 and the second electrode 240 attract each other, the driving bar 220 rotates clockwise (in the drawing) around the pivot (the second end of the vertical structure 210). Accordingly, the vertical portion 222 of the driving bar 220 and the central portion of the inductor coil 100 connected to the vertical portion 222 is raised. Herein, the driving bar 220 may vary the distance (height) by which the central portion of the inductor coil 100 is raised, depending on the magnitude (strength) of the electrostatic force between the first electrode 230 and the second electrode 240, thereby varying the inductance of the inductor coil 100.

Since the inductor coil 100 is in the loop, as the central portion is raised, the other portions (e.g., rings of the inductor coil 100) are also successively raised and a spiral shape results. Herein, in the vertical cross-section (e.g., FIG. 3), the center of the inductor coil 100 connected to the driving bar 220 is highest (raised most in height). In the vertical cross-section, the closer a particular ring of the inductor coil 100 is to the peripheral edge or circumference of the inductor coil 100, the smaller the distance between the substrate 10 and the inductor coil 100 (or the ring thereof).

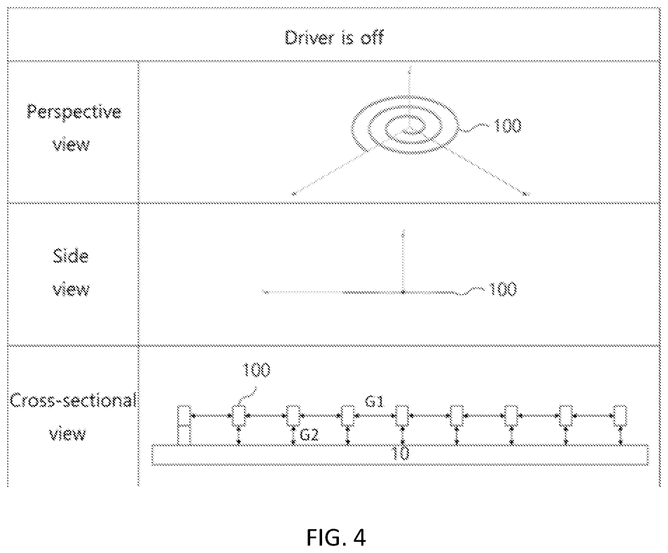

Referring to FIG. 4, when the driver 200 is off, the inductor coil 100 is planar, and parallel or substantially parallel over the substrate 10. That is, the inductor coil 100 forms a planar loop or coil, in which all turns or rings of the loop or coil are in the same plane.

When the driver 200 is off and the inductor coil 100 is planar, metal spacing G1 (or turn spacing) and substrate (10) spacing G2 are at the default (e.g., minimum) distances, which are also the inter-ring and substrate-inductor spacings at the time of manufacturing. Accordingly, the inductor coil 100 has the reference inductance value when the driver 200 is off. Herein, the metal spacing G1 may be defined as the distance between two adjacent turns or rings (metal structures in the cross-sectional view in FIG. 4) in the inductor coil 100, and the substrate (10) spacing G2 may be defined as a vertical distance between the inductor coil 100 (or a ring or turn thereof) and the substrate 10.

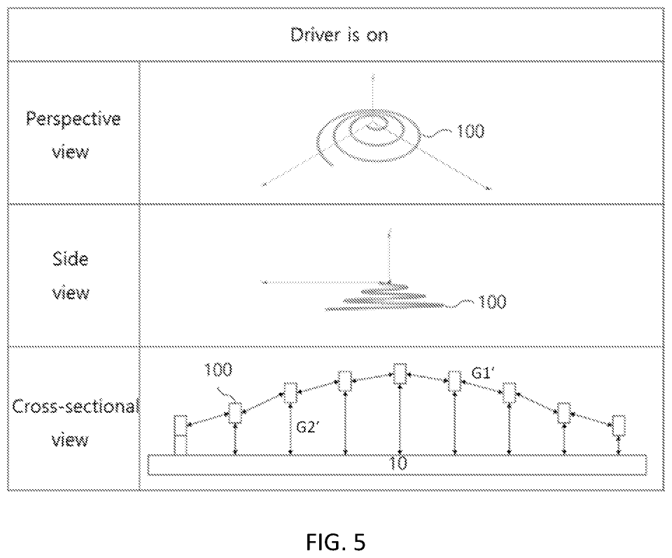

Referring to FIG. 5, when the driver 200 is on, the inductor coil 100 is raised, starting from its central portion connected to the driver 200. As the central portion of the inductor coil 100 is raised, the other portions (e.g., rings or turns) are also successively raised. In the vertical cross-section, the closer a particular ring of the inductor coil 100 is to the peripheral edge or circumference of the inductor coil 100, the smaller the spacing or distance between the substrate 10 and the inductor coil 100 (or the ring thereof). As a result, the inductor coil 100 forms a spiral-shaped coil, the metal spacing G1′ and substrate (10) spacing G2′ change, and the inductor coil 100 has an inductance different from the reference inductance value.

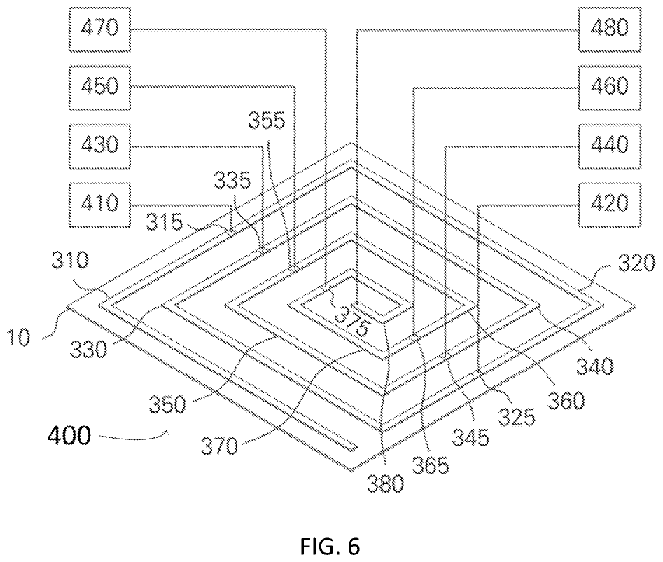

Referring to FIG. 6, a variable inductor or inductor module 400 according to a second embodiment of the present disclosure includes a plurality of split coils 310 to 380 and a plurality of drivers 410 to 480.

The plurality of split coils 310 to 380 are over a substrate 10. Herein, the plurality of split coils 310 to 380 are connected to each other to form an inductor coil or loop 400 that is wound multiple times over the substrate 10. The plurality of split coils 310 to 380 comprise a conductive material or metal, such as copper, silver, gold, aluminum or iron, for example.

The inductor coil 400 comprising the plurality of split coils 310 to 380 has an inductance that is proportional to the coil length, coil spacing, the number of turns in the coil, and the line width of the coil. Herein, an inductance of the inductor coil when all the plurality of split coils 310 to 380 are over and parallel to the substrate 10 is defined as the reference inductance value.

Each of the plurality of drivers 410 to 480 are connected to a corresponding one of the plurality of split coils 310 to 380, respectively. Each of the plurality of drivers 410 to 470 may be connected at a position 315, 325, 335, 345, 355, 365 and 375 at which one split coil is connected to another split coil. The plurality of drivers 410 to 480 are driven according to respective control signals, and raise or maintain the position of the respective split coils 310 to 380 so that the inductor coil 400 may have an inductance different from the reference inductance value. Herein, the drivers 410 to 480 may comprise micro-electromechanical system (MEMS) drivers, for example.

For example, the inductor coil 400 comprises a first split coil 310, a second split coil 320, a third split coil 330, a fourth split coil 340, a fifth split coil 350, a sixth split coil 360, a seventh split coil 370 and an eighth split coil 380.

A first end of the first split coil 310 may comprise a first output of the inductor coil 400. A second end of the first split coil 310 is connected to a first end of the second split coil 320 at a first connection location 315. A second end of the second split coil 320 is connected to a first end of the third split coil 330 at a second connection location 325. A second end of the third split coil 330 is connected to a first end of the fourth split coil 340 at a third connection location 335. A second end of the fourth split coil 340 is connected to a first end of the fifth split coil 350 at a fourth connection location 345. A second end of the fifth split coil 350 is connected to a first end of the sixth split coil 360 at a fifth connection location 355.

A second end of the sixth split coil 360 is connected to a first end of the seventh split coil 370 at a sixth connection location 365. A second end of the seventh split coil 370 is connected to a first end of the eighth split coil 380 at a seventh connection location 375. A second end of the eighth split coil 380 constitutes a second output part of the inductor coil.

The driver may include a first driver 410, a second driver 420, a third driver 430, a fourth driver 440, a fifth driver 450, a sixth driver 460, a seventh driver 470 and an eighth driver 480.

The first driver 410 is connected to the first connection location 315 at which the first split coil 310 and the second split coil 320 are connected. According to a corresponding first control signal, the first driver 410 may be turned on to raise the first connection location 315 or turned off to maintain the position of the first connection location 315 at the default position.

The second driver 420 is connected to the second connection location 325 at which the second split coil 320 and the third split coil 330 are connected. According to a corresponding second control signal, the second driver 420 may be turned on to raise the second connection location 325 or turned off to maintain the position of the second connection location 325 (e.g., at the default position).

The third driver 430 is connected to the third connection location 335 at which the third split coil 330 and the fourth split coil 340 are connected. According to a corresponding third control signal, the third driver 430 may be turned on to raise the third connection location 335 or turned off to maintain the position of the third connection location 335 (e.g., at the default position).

The fourth driver 440 is connected to the fourth connection location 345 at which the fourth split coil 340 and the fifth split coil 350 are connected. According to a corresponding fourth control signal, the fourth driver 440 may be turned on to raise the fourth connection location 345 or turned off to maintain the position of the fourth connection location 345 (e.g., at the default position).

The fifth driver 450 is connected to the fifth connection location 355 at which the fifth split coil 350 and the sixth split coil 360 are connected. According to a corresponding fifth control signal, the fifth driver 450 may be turned on to raise the fifth connection location 355 or turned off to maintain the position of the fifth connection location 355 (e.g., at the default position).

The sixth driver 460 is connected to the sixth connection location 365 at which the sixth split coil 360 and the seventh split coil 370 are connected. According to a corresponding sixth control signal, the sixth driver 460 may be turned on to raise the sixth connection location 365 or turned off to maintain the position of the sixth connection location 365 (e.g., at the default position).

The seventh driver 470 is connected to the seventh connection location 375 at which the seventh split coil 370 and the eighth split coil 380 are connected. According to a corresponding seventh control signal, the seventh driver 470 may be turned on to raise the seventh connection location 375 or turned off to maintain the position of the seventh connection location 375 (e.g., at the default position).

The eighth driver 480 is connected to a position at or adjacent to the second end of the eighth split coil 380. According to a corresponding eighth control signal, the eighth driver 480 may be turned on to raise the second end of the eighth split coil 380 or turned off to maintain the position of the second end of the eighth split coil 380 (e.g., at the default position).

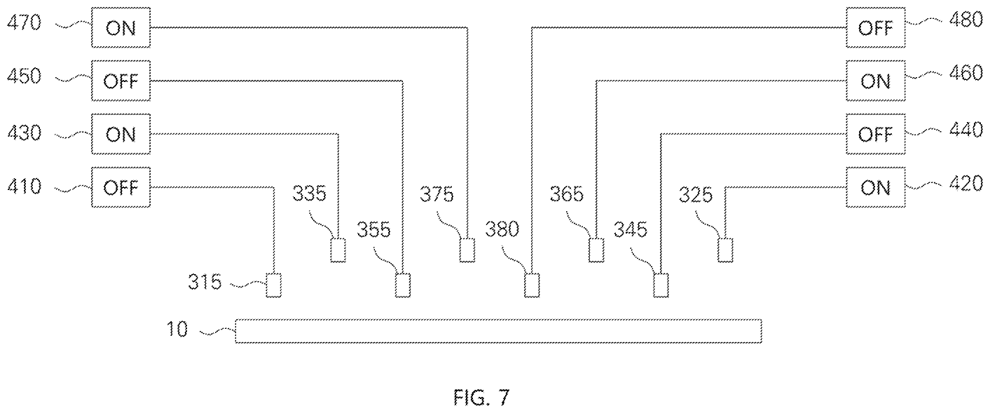

Referring to FIG. 7, the first driver 410 is turned off according to the first control signal to maintain the current position (that is, the default position over the substrate 10) of the first connection location 315. The second driver 420 is turned on according to the second control signal to raise the second connection location 325. The third driver 430 is turned on according to the third control signal to raise the third connection location 335. The fourth driver 440 is turned off according to the fourth control signal to maintain the current position (that is, over the substrate 10) of the fourth connection location 345. The fifth driver 450 is turned off according to the fifth control signal to maintain the current position (that is, over the substrate 10) of the fifth connection location 355. The sixth driver 460 is turned on according to the sixth control signal to raise the sixth connection location 365. The seventh driver 470 is turned on according to the seventh control signal to raise the seventh connection location 375. The eighth driver 480 is turned off according to the eighth control signal to maintain the current position (that is, the default position over the substrate 10) of the second end of the eighth split coil 380.

Accordingly, the plurality of split coils 310 to 380 forming the inductor coil 400 may have a “wave” structure that repeats alternating raised and default positions of the first through seventh connection locations 315, 325, 335, 345, 355, 365 and 375 and the second end of the eighth split coil 380 over the substrate 10, and changes the inter-metal spacing, the substrate (10)-inductor coil 400 spacing, and the inductance (i.e., to be different from the reference inductance value).

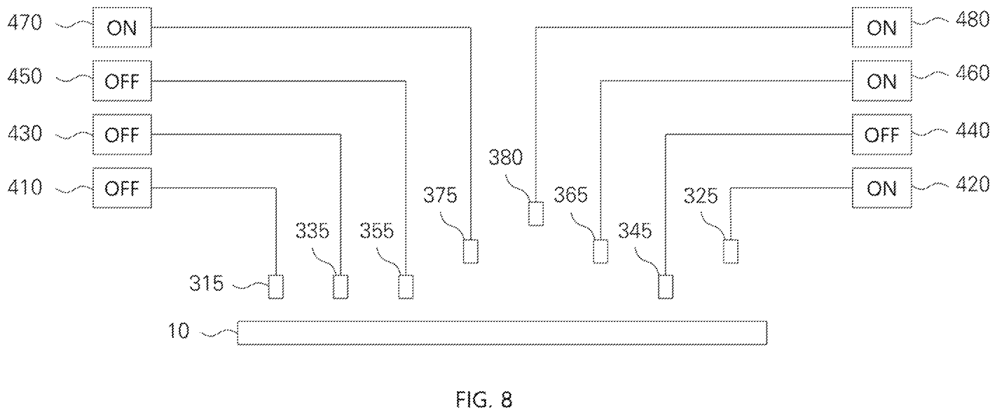

Referring to FIG. 8, the first driver 410, the third driver 430, the fourth driver 440, and the fifth driver 450 are turned off according to the corresponding first, third, fourth and fifth control signals to maintain the current positions of the first connection location 315, the third connection location 335, the fourth connection location 345, and the fifth connection location 355 at the default position. The second driver 420, the sixth driver 460, the seventh driver 470, and the eighth driver 480 are turned on according to the corresponding second, sixth, seventh and eighth control signals to raise the second connection location 325, the sixth connection location 365, the seventh connection location 375, and the eighth split coil 380 to various distances above the substrate 10. In the example shown in FIG. 8, because the eighth split coil 380 is raised relative to the already-raised sixth and seventh connection locations 365 and 375, the eighth split coil 380 may be raised a multiple (in this case, two [2]) increments in distance above the default position.

In the meantime, although not shown in the drawing, when all the first driver 410 to the eighth driver 480 are turned on, the plurality of split coils 310 to 380 may change the shape of the inductor coil 400 to a spiral.

In this way, the inductor coil 400 comprising the plurality of split coils 310 to 380 may have a variety of different shapes, such as a wave or a spiral shape, over the substrate 10, and a variety of different inter-metal spacings and substrate 10-inductor coil 400 spacings and any of a large variety of inductances different from the reference inductance value. Herein, the variable inductor or inductor module 400 shown in FIG. 8 may have an inductance the same as or different from the variable inductor or inductor module 400 shown in FIG. 7.

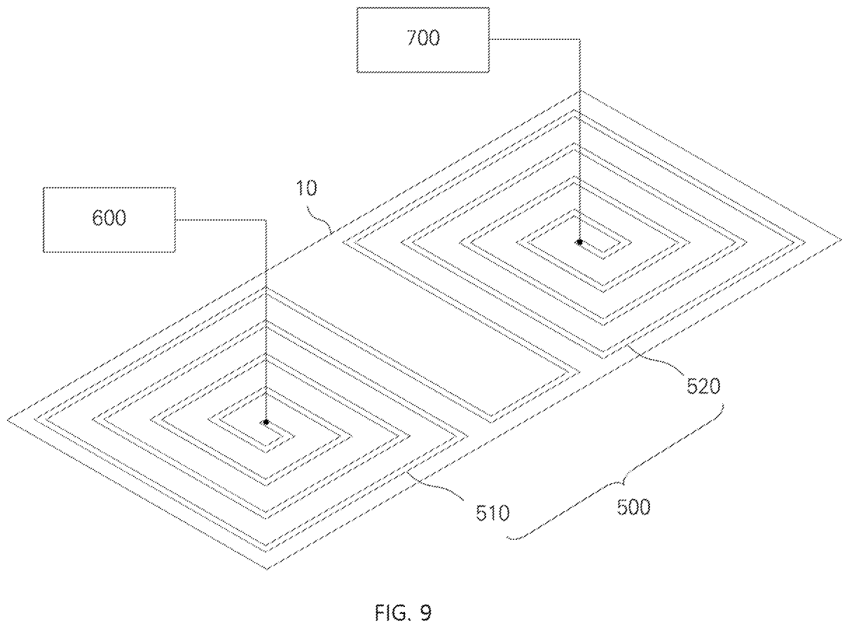

Referring to FIG. 9, a variable inductor or inductor module according to a third embodiment of the present disclosure includes a multi-coil inductor 500, a first driver 600, and a second driver 700. The multi-coil inductor 500 is over a substrate 10. The multi-coil inductor 500 comprises a conductive material such as a metal, for example, copper, silver, gold, aluminum or iron.

The multi-coil inductor 500 includes a first coil 510 that is wound multiple times over the substrate 10 and a second coil 520 that is also wound multiple times over the substrate 10. Herein, a first end of the first coil 510 may constitute a first output of the multi-coil inductor 500, a second end of the first coil 510 is connected to a first end of the second coil 520, and a second end of the second coil 520 may constitute a second output of the multi-coil inductor 500.

Herein, the first coil 510 and the second coil 520, taken together, are shown and described as being one integrated coil, but the invention is not limited thereto. The first coil 510 and the second coil 520 may be separate (e.g., manufactured individually), and the first coil 510 and the second coil 520 may be electrically connected to or in electromagnetic communication with each other.

The multi-coil inductor 500 comprising the first coil 510 and the second coil 520 has an inductance that is proportional to the coil length, coil spacing, the number of turns in the coil, and the line width of the coil. Herein, the inductance of the multi-coil inductor 500 when the entire multi-coil inductor 500 is in a default position over the substrate 10 is defined as a reference inductance value.

The first driver 600 is connected to the first coil 510, and more specifically, the first driver 600 is connected to the first coil 510 at a central portion (e.g., the center) of the first coil 510. That is, the first driver 600 may be connected to the first end of the first coil 510. The first driver 600 is driven according to a first control signal and changes the distance or spacing between the first coil 510 and the substrate 10, as well as the spacing between rings or turns of the first coil 510. Herein, the first driver 600 raises the center or first end of the first coil 510 when turned on and, when turned off, returns the center or first end of the first coil 510 to the default position or maintains the center or first end of the first coil 510 at the default position.

The second driver 700 is connected to the second coil 520, and more specifically, the second driver 700 is connected to the second coil 520 at a central portion (e.g., the center) of the second coil 520. That is, the second driver 700 may be connected to the second end of the second coil 520. The second driver 700 is driven according to a second control signal and changes the distance or spacing between the second coil 520 and the substrate 10, as well as the spacing between rings or turns of the second coil 520. Herein, the second driver 700 raises the center or second end of the second coil 520 when turned on and, when turned off, returns the center or second end of the second coil 520 to the default position or maintains the center or second end of the second coil 520 at the default position when turned off.

The first driver 600 and the second driver 700 control the raising and lowering of the first coil 510 and the second coil 520 individually and/or independently according to respective first and second control signals. When the first driver 600 and/or the second driver 700 raise the first coil 510 and/or the second coil 520, the inductance of the multi-coil inductor 500 differs from its reference inductance value. Herein, the first driver 600 and the second driver 700 may comprise micro-electromechanical system (MEMS) drivers, for example.

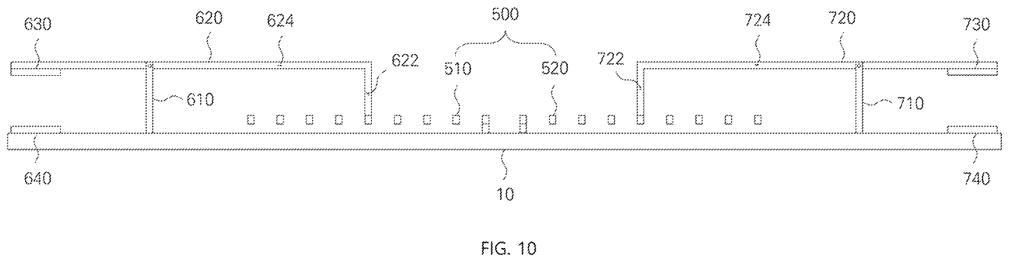

For example, referring to FIG. 10, the first driver 600 includes a first vertical structure 610, a first driving bar 620, a first electrode 630, and a second electrode 640.

The first vertical structure 610 elevates the first driving bar 620 from the substrate to a position or height above the first coil 510 and functions as a pivot for the first driving bar 620. A first end of the first vertical structure 610 is connected to the substrate 10, and a second end of the first vertical structure 610 is connected to the first driving bar 620. Herein, the second end of the first vertical structure 610 is connected to the first driving bar 620 such that the first driving bar 620 is rotatable around the second end of the first vertical structure 610 (i.e., the pivot).

The first driving bar 620 raises the first coil 510 of the multi-coil inductor 500 or maintains the first coil 510 in the default position. The first driving bar 620 includes a first vertical portion 622 and a first horizontal portion 624.

A first end of the first vertical portion 622 is connected to the first end of the first coil 510. A second end of the first vertical portion 622 is connected to the first horizontal portion 624.

A first end of the first horizontal portion 624 is connected to the second end of the first vertical portion 622. Thus, the first driving bar 620 has a bent shape (e.g., an “L” shape), for example.

The first horizontal portion 624 is connected to the second end of the first vertical structure 610 such that the first horizontal portion 624 is rotatable around the second end of the first vertical structure 610. Herein, the first vertical structure 610 is between the first end of the first horizontal portion 624 and a second end of the first horizontal portion 624, and has a height from the substrate 10 significantly greater than the height of the first coil 510 from the substrate 10. Herein, the second end of the first horizontal portion 624 is an end opposite to the first end of the first horizontal portion 624.

The first electrode 630 receives a first voltage (e.g., from a driving circuit [not shown] elsewhere on the substrate, or external to the substrate) that may form an electrostatic force (e.g., between it and a voltage on the second electrode 640). The first electrode 630 is may be on the first driving bar 620 (e.g., on a surface facing the substrate 10). Specifically, the first electrode 630 is at or close to the second end of the first horizontal portion 624. Accordingly, the first electrode 630 is may be at one end of the first horizontal portion 624 of the first driving bar 620, with the connection position between the first vertical structure 610 and the first driving bar 620 in the middle of the first horizontal portion 624.

The second electrode 640 that receives a second voltage (e.g., from the same or different driving circuit on or external to the substrate that provides the first voltage) and may form an electrostatic force between it and the first electrode 630. The second electrode 640 is on the substrate 10. More specifically, the second electrode 640 at least partially overlaps the first electrode 630.

Herein, the first electrode 630 and the second electrode 640 attract each other as the electrostatic force increases, thereby raising the first vertical portion 622 of the first driving bar 620. The attractive force between the first electrode 630 and the second electrode 640 decreases as the electrostatic force decreases, thereby lowering the first vertical portion 622 of the first driving bar 620 towards the default position.

The second driver 700 includes a second vertical structure 710, a second driving bar 720, a third electrode 730, and a fourth electrode 740.

The second vertical structure 710 elevates the second driving bar 720 from the substrate to a position or height above the second coil 520 and functions as a pivot for the second driving bar 720. A first end of the second vertical structure 710 is connected to the substrate 10, and a second end of the second vertical structure 710 is connected to the second driving bar 720. Herein, the second end of the second vertical structure 710 is connected to the second driving bar 720 such that the second driving bar 720 is rotatable around the second end of the second vertical structure 710 (i.e., the pivot).

The second driving bar 720 raises the second coil 520 of the multi-coil inductor 500 or maintains the second coil 520 in the default position. The second driving bar 720 includes a second vertical portion 722 and a second horizontal portion 724.

A first end of the second vertical portion 722 is connected to the second end of the second coil 520. A second end of the second vertical portion 722 is connected to the second horizontal portion 724.

A first end of the second horizontal portion 724 is connected to the second end of the second vertical portion 722. Thus, the second driving bar 720 has a bent shape (e.g., an “L” shape), for example.

The second horizontal portion 724 is connected to the second end of the second vertical structure 710 such that the second horizontal portion 724 is rotatable around the second end of the second vertical structure 710. Herein, the second vertical structure 710 is between the first end of the second horizontal portion 724 and a second end of the second horizontal portion 724, and has a height from the substrate 10 significantly greater than the height of the second coil 520 from the substrate 10. Herein, the second end of the second horizontal portion 724 is an end opposite to the first end of the second horizontal portion 724.

The third electrode 730 receives a first voltage (e.g., from a driving circuit [not shown] elsewhere on the substrate, or external to the substrate) that may form an electrostatic force (e.g., between it and a voltage on the fourth electrode 740). The third electrode 730 is may be on the second driving bar 720 (e.g., on a surface facing the substrate 10). Specifically, the third electrode 730 is at or close to the second end of the second horizontal portion 724. Accordingly, the third electrode 730 is may be at one end of the second horizontal portion 724 of the second driving bar 720, with the connection position between the second vertical structure 710 and the second driving bar 720 in the middle of the second horizontal portion 724.

The fourth electrode 740 that receives a second voltage (e.g., from the same or different driving circuit on or external to the substrate that provides the first voltage) and may form an electrostatic force between it and the third electrode 730. The fourth electrode 740 is on the substrate 10. More specifically, the fourth electrode 740 at least partially overlaps the third electrode 730.

Herein, the third electrode 730 and the fourth electrode 740 attract each other as the electrostatic force increases, thereby raising the second vertical portion 722 of the second driving bar 720. The attractive force between the third electrode 730 and the fourth electrode 740 decreases as the electrostatic force decreases, thereby lowering the second vertical portion 722 of the second driving bar 720 towards the default position.

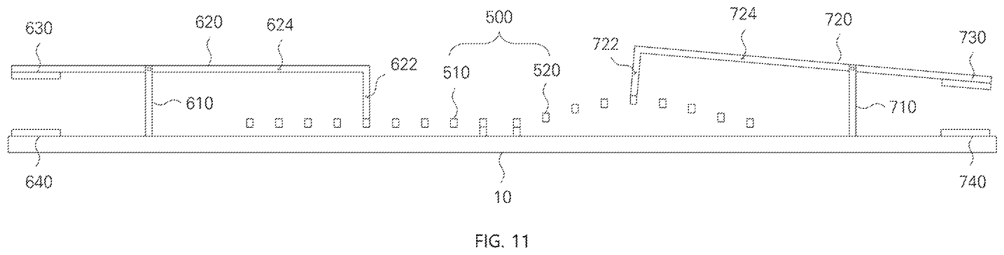

Referring to FIG. 11, the first control signal turns off the first driver 600, and the second control signal turns on the second driver 700.

In response to the first control signal, an electrostatic force of zero or approximately zero is between the first electrode 630 and the second electrode 640 of the first driver 600 (i.e., the electrostatic force is not applied to the first electrode 630 and the second electrode 640). Accordingly, the default position of the first coil 510 of the multi-coil inductor 500 is maintained.

In response to the second control signal, a non-zero electrostatic force is between the third electrode 730 and the fourth electrode 740 of the second driver 700, and an attractive force draws the third electrode 730 and the fourth electrode 740 towards each other. As the third electrode 730 and the fourth electrode 740 attract each other, the second driving bar 720 rotates clockwise (in the drawing) around the second end of the second vertical structure 710. Accordingly, the second vertical portion 722 of the second driving bar 720 and the central portion of the second coil 520 connected to the second vertical portion 722 are raised. Herein, the second driving bar 720 varies the distance (height) by which the central portion (that is, the second end) of the second coil 520 is raised from the substrate 10, depending on the magnitude (strength) of the electrostatic force between the third electrode 730 and the fourth electrode 740.

As the central portion (that is, the second end) of the second coil 520 is raised, other portions of the second coil 520 are also raised. Herein, in the vertical cross-section, the central portion (that is, the second end) of the second coil 520 connected to the second driving bar 720 is raised the most. In the vertical cross-section, the closer a particular ring of the second coil 520 is to the peripheral edge or circumference of the second coil 520, the smaller the distance between the substrate 10 and the second coil 520 (or the ring thereof).

As the first coil 510 maintains its planar configuration and the second driver 700 changes the second coil 520 into a spiral configuration, the multi-coil inductor 500 has an inductance different from its reference inductance value.

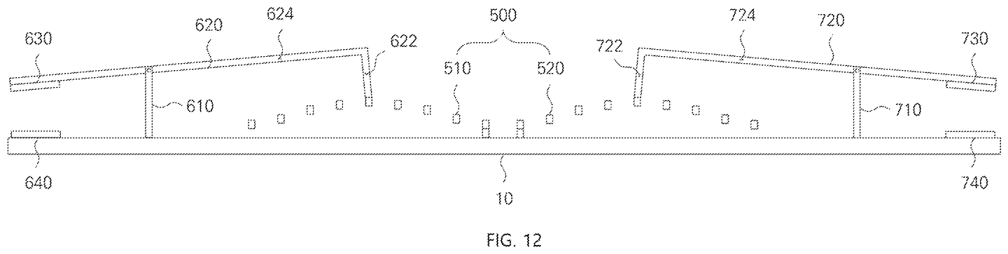

Referring to FIG. 12, first and second control signals are input to the first driver 600 and the second driver 700 to turn on the first driver 600 and the second driver 700. In this example (as well as the examples of FIGS. 5, 7, 8 and 11), the control signals may be digital and/or have digital driving states (i.e., have one of only an “active” or “inactive” state, or an “on” or “off” state, or a “1” or “0” state), but the invention is not limited to digital control signals to the drivers.

In response to the first control signal, a non-zero electrostatic force is between the first electrode 630 and the second electrode 640, and an attractive force draws them towards each other. As the first electrode 630 and the second electrode 640 attract each other, the first driving bar 620 rotates counterclockwise (in the drawing) around the second end of the first vertical structure 610. Accordingly, the first vertical portion 622 of the first driving bar 620 and the central portion of the first coil 510 connected to the first vertical portion 622 are raised. When the control signal is multi-bit or analog (i.e., can have any of many possible values between zero and a predetermined maximum value), the first driving bar 620 may vary the distance (height) by which the central portion (that is, the first end) of the first coil 510 is raised, depending on the magnitude (strength) of the electrostatic force between the first electrode 630 and the second electrode 640.

As the central portion (that is, the first end) of the first coil 510 is raised, other portions of the first coil 510 are also raised. Herein, in the vertical cross-section, the central portion (that is, the first end) of the first coil 510 connected to the first driving bar 620 is raised the most. In the vertical cross-section, the closer a particular ring of the first coil 510 is to the peripheral edge or circumference of the first coil 510, the smaller the distance between the substrate 10 and the first coil 510 (or the ring thereof).

In response to the second control signal, a non-zero electrostatic force is between the third electrode 730 and the fourth electrode 740, and an attractive force draws them towards each other. As the third electrode 730 and the fourth electrode 740 attract each other, the second driving bar 720 rotates clockwise (in the drawing) around the second end of the second vertical structure 710. Accordingly, the second vertical portion 722 of the second driving bar 720 and the central portion of the second coil 520 connected to the second vertical portion 722 are raised. When the control signal is multi-bit or analog (i.e., can have any of many possible values between zero and a predetermined maximum value), the second driving bar 720 may vary the distance (height) by which the central portion (that is, the second end) of the second coil 520 is raised, depending on the magnitude (strength) of the electrostatic force between the third electrode 730 and the fourth electrode 740.

As the central portion (that is, the second end) of the second coil 520 is raised, other portions of the second coil 520 are also raised. Herein, in the vertical cross-section, the central portion (that is, the second end) of the second coil 520 connected to the second driving bar 720 is raised the most. In the vertical cross-section, the closer a particular ring of the first coil 510 is to the peripheral edge or circumference of the second coil 520, the smaller the distance between the substrate 10 and the second coil 520 (or the ring thereof).

As the first driver 600 and the second driver 700 change the first coil 510 and the second coil 520 into spiral configurations, the multi-coil inductor 500 has an inductance different from its reference inductance value and from the configuration shown in FIG. 11.

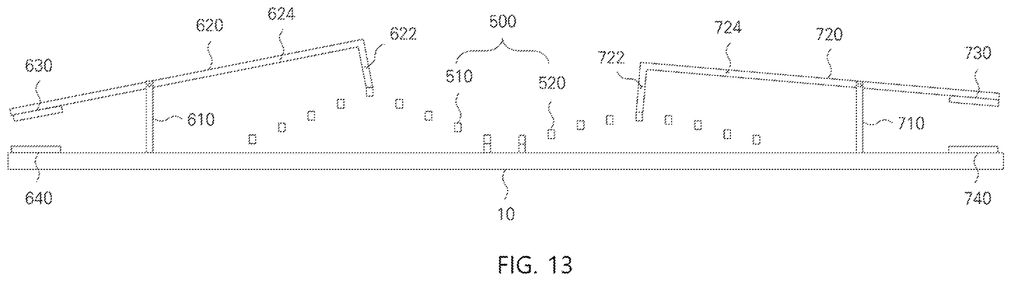

Referring to FIG. 13, the first driver 600 and the second driver 700 receive respective multi-bit or analog control signals having different control values. Consequently, the distance by which the first end of the first coil 510 is raised from the substrate 10 differs from the distance by which the second end of the second coil 520 is raised.

Although the exemplary embodiments of the present disclosure have been described, those skilled in the art will appreciate that various modifications, additions and substitutions are possible, without departing from the scope and spirit of the disclosure as disclosed in the accompanying claims.

What is claimed is:

1. A variable inductor or inductor module, comprising:
a substrate;
an inductor coil above the substrate, and having a reference inductance value; and
a micro-electromechanical system (MEMS) driver that responds to an electrostatic force, configured to be turned on or off in response to a control signal and is configured to increase a distance between at least part of the inductor coil and the substrate when the MEMS driver is turned on, and to maintain the inductor coil in a default position when turned off.

2. The variable inductor or inductor module of claim 1, wherein the inductor coil has an inductance value different from the reference inductance value when the driver is turned on.

3. The variable inductor or inductor module of claim 1, wherein inductor coil comprises a loop, the driver is connected to a central portion of the loop, and the inductor coil has a spiral shape when the driver is turned on so that spacing between (i) adjacent rings of the inductor coil and (ii) the substrate and the inductor coil change.

4. The variable inductor or inductor module of claim 3, wherein the inductor coil is configured such that, when the driver is turned on, the closer one of the rings is to a peripheral edge or circumference of the inductor coil, the smaller the distance between the substrate and the ring.

5. The variable inductor or inductor module of claim 1, wherein the driver comprises:
a vertical structure connected to the substrate;
a driving bar connected to the inductor coil, and configured to raise or lower the inductor coil by rotating around a pivot;
a first electrode on the driving bar; and
a second electrode on the substrate and at least partially overlapping the first electrode.

6. The variable inductor or inductor module of claim 5, wherein the driving bar comprises:
a vertical portion having a first end connected to the inductor coil; and
a horizontal portion having a first end connected to a second end of the vertical portion, wherein the horizontal portion is rotatable around the pivot.

7. The variable inductor or inductor module of claim 1, wherein the driver is configured to control the distance between the inductor coil and the substrate depending on a magnitude of the electrostatic force, and
the inductor coil is has a different inductance value depending on the electrostatic force.

8. A variable inductor or inductor module, comprising:
a substrate;
an inductor coil comprising a plurality of split coils connected to each other above the substrate, the inductor coil having a reference inductance value; and
a plurality of micro-electromechanical system (MEMS) drivers that respond to a plurality of electrostatic forces, wherein the plurality of MEMS drivers are respectively connected to the plurality of split coils, configured to be turned on or off in response to a plurality of control signals, and configured to increase a distance between the split coils and the substrate when turned on, and to maintain the split coils in a default position when turned off.

9. The variable inductor or inductor module of claim 8, wherein the inductor coil that the plurality of split coils constitute is has an inductance value different from the reference inductance value when at least one of the plurality of drivers is turned on and/or at least one distance between at least one of the plurality of split coils and the substrate increases.

10. The variable inductor or inductor module of claim 8, wherein the plurality of split coils have any of a plurality of different distances from the substrate depending on a magnitude of the electrostatic forces.

11. The variable inductor or inductor module of claim 8, wherein each of the plurality of drivers is connected to the inductor coil at a position at which one of the split coils and another one of the split coils are connected to each other.

12. A variable inductor or inductor module, comprising:
a substrate;
a multi-coil inductor comprising a first coil and a second coil above the substrate, and having inductance values;
a first micro-electromechanical system (MEMS) driver that responds to a first electrostatic force, configured to be turned on or off in response to a first control signal, and configured to increase a first distance between the first coil and the substrate when turned on, and to maintain the first coil in a first default position when turned off; and
a second MEMS driver that responds to a second electrostatic force, configured to be turned on or off in response to a second control signal, and configured to increase a second distance between the second coil and the substrate when turned on, and to maintain the second coil in a second default position when turned off.

13. The variable inductor or inductor module of claim 12, wherein the inductor coil has any of a plurality of different inductance values depending on driving states of the first driver and the second driver.

14. The variable inductor or inductor module of claim 12, wherein the first driver is connected to a central portion of the first coil, and
when the first driver is turned on, spacing between adjacent rings of the first coil and the distance between the substrate and the first coil change.

15. The variable inductor or inductor module of claim 14, wherein the first coil has a spiral shape, and when the first driver is turned on, the closer one of the rings is to a peripheral edge or circumference of the first coil, the smaller the distance between the substrate and the ring.

16. The variable inductor or inductor module of claim 12, wherein the second driver is connected to a central portion of the second coil, and
when the second driver is turned on, spacing between (i) adjacent rings of the second coil and (ii) the substrate and the second coil change.

17. The variable inductor or inductor module of claim 16, wherein the second coil has a spiral shape, and when the second driver is turned on, the closer one of the rings is to a peripheral edge or circumference of the second coil, the smaller the distance between the substrate and the ring.

18. The variable inductor or inductor module of claim 12, wherein the first driver and the second driver respectively receive independent first and second control signals, and when the first and second control signals have different values, the distance of the first coil from the substrate differs from the distance of the second coil from the substrate.

19. The variable inductor or inductor module of claim 12, wherein the first driver comprises:
a first vertical structure connected to the substrate;
a first driving bar connected to the first coil, and configured to raise or lower the first coil by rotating around a first pivot;
a first electrode on the first driving bar; and
a second electrode on the substrate and at least partially overlapping the first electrode, and the first driving bar comprises:
a first vertical portion having a first end connected to the first coil; and
a first horizontal portion having a first end connected to a second end of the first vertical portion, and connected to the first vertical structure such that the first horizontal portion is rotatable around the first pivot.

20. The variable inductor or inductor module of claim 12, wherein the second driver comprises:
a second vertical structure connected to the substrate;
a second driving bar connected to the second coil, and configured to raise or lower the second coil by rotating around a second pivot;
a third electrode on the second driving bar; and
a fourth electrode on the substrate and at least partially overlapping the third electrode,
wherein the second driving bar comprises:
a second vertical portion having a first end connected to the second coil; and
a second horizontal portion having a first end connected to a second end of the second vertical portion, and connected to the second vertical structure such that the second horizontal portion is rotatable around the second pivot.
